(19) United States
(12) Patent Application Publication
(10) Pub. No.: US 2005/0212593 A1
(43) Pub. Date: Sep. 29, 2005

(54) Semiconductor circuit

(75) Inventor: Katsuhiko Morosawa, Tachikawa-shi (JP)

Correspondence Address: FRISHAUF, HOLTZ, GOODMAN & CHICK, PC, 220 5TH AVE FL 16, NEW YORK, NY, 10001-7708, US

(73) Assignee: Casio Computer Co., Ltd., Tokyo (JP)

(21) Appl. No.: 11/087,973

(22) Filed: Mar. 23, 2005

(30) Foreign Application Priority Data
Mar. 26, 2004 (JP) 2004-092971

(51) Int. Cl. H03F 1/36

(52) U.S. Cl. 330/85

(57) ABSTRACT

An output circuit which outputs an output signal voltage corresponding to an input signal voltage in a semiconductor circuit of this invention includes first and second voltage follower circuits. The input signal voltage is applied to the first voltage follower circuit from which the output signal voltage is output. The output signal voltage is negatively fed back to the first voltage follower circuit through the second voltage follower circuit so that the shift between the input and output signal voltages is suppressed. The first and second voltage follower circuits include a plurality of thin-film transistors.

### CROSS-REFERENCE TO RELATED APPLICATIONS

This application is based upon and claims the benefit of priority from prior Japanese Patent Application No. 2004-092971, filed Mar. 26, 2004, the entire contents of which are incorporated herein by reference.

### BACKGROUND OF THE INVENTION

1. Field of the Invention

The present invention relates to an output circuit and a driving circuit having the output circuit and, more particularly, to an output circuit which is preferably arranged by using thin-film transistors and outputs an output signal voltage to drive a display pixel in an image display device, and a driving circuit having the output circuit.

2. Description of the Related Art

As information display units (display devices) in image pick-up devices such as digital video cameras and digital still cameras, or portable devices such as cellular phones and personal digital assistants (PDAs), which are very popular in recent years, thin and lightweight liquid crystal display devices having a liquid crystal display panel, low power consumption, and excellent display image quality are often used.

As the next-generation display devices following the liquid crystal display devices, self-luminescence type display devices have intensively been researched and developed for practical use. Such a self-luminescence type display device has a display panel on which self-luminescence type elements such as organic electroluminescent elements (organic EL elements), inorganic electroluminescent elements (inorganic EL elements), or light-emitting diodes (LEDs) are formed as display pixels. Unlike the liquid crystal display devices, the self-luminescence type display devices have no dependence on view angle and require no backlight, and therefore, can be made more thin and lightweight.

Such a liquid crystal display device or self-luminescence type display device generally includes a display panel having a plurality of display pixels arrayed two-dimensionally, a scan driver circuit which sequentially scans the display pixels of each row of the display panel and sets them in the selected state, and a signal driver circuit which outputs at once a display signal voltage based on a video signal to the display pixels of the row set in the selected state.

In the technological field of semiconductor integrated circuits, a thin-film transistor using low-temperature or cold polysilicon (to be referred to as a polysilicon thin-film transistor hereinafter) have received a great deal of attention. Cold polysilicon has various advantageous properties. For example, cold polysilicon is easy to manufacture at a low cost as compared to single-crystal silicon and has a higher carrier mobility than amorphous silicon.

Such the polysilicon thin-film transistor can be formed in a relatively low-temperature environment at about 500° C. For this reason, the polysilicon thin-film transistor can satisfactorily be formed on a conventional glass substrate used for a display panel such as a liquid crystal display panel or organic EL panel. The driving circuit in the display device can be also formed integrally with the display panel.

When the driving circuit is formed integrally with the display panel, the number of interconnections between the display panel and external circuits can largely be reduced. In addition, the mounting area of driver ICs can be reduced. Hence, the total area of the driving circuit portions can be reduced, and the outer peripheral portion of the display surface can be narrowed.

The driving circuit in the display device is designed such that a display signal voltage having an analog signal voltage is output from the signal driver circuit and supplied to the display pixels. The signal driver circuit has an output circuit unit which outputs the display signal voltage. The output circuit unit sometimes includes a buffer circuit to, e.g., enhance an output signal voltage as the display signal voltage.

FIG. 8 is a circuit diagram showing an arrangement of a buffer circuit according to a prior art.

FIG. 9 is a circuit diagram showing an example of a circuit arrangement of an operational amplifier used in the buffer circuit according to the prior art.

When a signal driver circuit is formed from transistors made of single-crystal silicon, for example, a voltage follower circuit having an arrangement shown in FIG. 8 is used as a buffer circuit. As shown in FIG. 8, the voltage follower circuit used as a buffer circuit 9 comprises an operational amplifier 90. The operational amplifier 90 comprises a noninverting input terminal 91, inverting input terminal 92, and output terminal 93. The output terminal 93 and inverting input terminal 92 are electrically connected. An input signal voltage Vin is applied to the noninverting input terminal 91, and an output signal voltage Vout is output from the output terminal 93. In addition, the output signal voltage Vout is negatively fed back to the inverting input terminal 92. Since the output signal voltage is always negatively fed back, the input signal voltage Vin always equals the output signal voltage Vout. For example, a circuit arrangement as shown in FIG. 9 is used to the operational amplifier 90. The operational amplifier 90 includes a plurality of transistors.

The output circuit unit of the signal driver circuit outputs the display signal voltage to drive the display panel at a gradation based on the video signal. To accurately control the gradation of the display panel, the buffer circuit of the output circuit unit is especially required to output a correct output signal voltage value in correspondence with the input signal voltage value, i.e., accurately output the output signal voltage. When the buffer circuit is formed from transistors made of single-crystal silicon, a necessary and sufficient accuracy is obtained in the circuit arrangement.

However, no satisfactory output characteristic is obtained when the driving circuit is formed by using the above-described polysilicon thin-film transistors and, more specifically, when the same arrangement as the buffer circuit 9 including a voltage follower circuit shown in FIG. 8 is applied to the buffer circuit arranged in the output circuit unit of the signal driver circuit formed from polysilicon thin-film transistors.

FIGS. 10A and 10B are graphs showing results obtained by simulating the input/output characteristic of the buffer circuit of the prior art, which includes polysilicon thin-film transistors.

As the ideal input/output characteristic of the buffer circuit, the value of the output signal voltage equals the value of the input signal voltage, as indicated by the dotted line in FIG. 10A. When the voltage follower circuit used as the buffer circuit of the prior art is constituted by using polysilicon thin-film transistors, the shift of the value of the output signal voltage Vout is large especially in regions (Vin≈Vdd, Vin≈Vss) where the input signal voltage Vin is close to the high-level power supply voltage or low-level power supply voltage (Vdd or Vss), as shown in FIG. 10A. In these regions, the accuracy of the output signal voltage decreases. This occurs due to the electrical characteristic of the polysilicon thin-film transistor. The polysilicon thin-film transistor has an electrical characteristic poorer than a transistor made of single-crystal silicon with excellent characteristics such as a relatively high threshold voltage and relatively low electron mobility. That is, in the conventional buffer circuit using a voltage follower circuit formed from polysilicon thin-film transistors, the electrical characteristic of the polysilicon thin-film transistor is poor especially when the input signal voltage is close to the positive or negative power supply voltage, i.e., when the potential difference between the input signal voltage and the source electrode or drain electrode is small. Hence, in that region, the feedback operation of the output signal voltage Vout is not sufficiently done. For this reason, the shift of the output signal voltage becomes large.

As described above, when the driving circuit is formed by using polysilicon thin-film transistors, the accuracy of the output signal voltage with respect to the input signal voltage to the buffer circuit in the output circuit unit of the signal driver is poor. For this reason, display gradation control in the display panel cannot accurately be executed, and the display quality becomes poor.

### BRIEF SUMMARY OF THE INVENTION

The present invention advantageously makes it possible to, in an output circuit constituted by using thin-film transistors and a driving circuit having the output circuit, suppress any shift of the output signal voltage with respect to the input signal voltage, and apply the output circuit to the driving circuit of a display device to execute accurate gradation control and obtain a high display quality.

In order to achieve the above advantage, according to an aspect of the present invention, there is provided an output circuit which outputs an output signal voltage corresponding to an input signal voltage comprising at least a first voltage follower circuit and a second voltage follower circuit, wherein the input signal voltage is applied to the first voltage follower circuit, and the output signal voltage is output, and the output signal voltage is negatively fed back to the first voltage follower circuit through the second voltage follower circuit.

The first voltage follower circuit and the second voltage follower circuit can include a plurality of thin-film transistors. Each thin-film transistor comprises, e.g., a polysilicon thin-film transistor.

Preferably, the first voltage follower circuit includes a plurality of first thin-film transistors, the second voltage follower circuit includes a plurality of second thin-film transistors, the first voltage follower circuit and the second voltage follower circuit have the same circuit arrangement, and one of the plurality of second thin-film transistors corresponding to one of the first thin-film transistors has the same transistor size. Alternatively, one of the plurality of second thin-film transistors corresponding to one of the first thin-film transistors has the same ratio of a channel length to a channel width, and the channel width of the second thin-film transistor can be set smaller than the channel width of the first thin-film transistor.

Preferably, the first voltage follower circuit has a first noninverting input terminal, a first inverting input terminal, and a first output terminal, the second voltage follower circuit has a second noninverting input terminal, a second inverting input terminal, and a second output terminal, the first output terminal is connected to the second noninverting input terminal, and the second output terminal is connected to the second inverting input terminal and the first inverting input terminal. Preferably, the first voltage follower circuit has a first operational amplifier which has the first noninverting input terminal, the first inverting input terminal, and the first output terminal, the second voltage follower circuit has a second operational amplifier which has the second noninverting input terminal, the second inverting input terminal, and the second output terminal, and the first operational amplifier and the second operational amplifier have the same input/output characteristic.

In order to achieve the above advantage, according to another aspect of the present invention, there is provided a driving device which drives a pixel, comprising an output circuit unit to which an input signal voltage corresponding to input data is applied and which outputs an output signal voltage corresponding to the input signal voltage to the pixel, the output circuit unit comprising at least a first voltage follower circuit and a second voltage follower circuit, wherein the input signal voltage is applied to the first voltage follower circuit, and the output signal voltage is output, and the output signal voltage is negatively fed back to the first voltage follower circuit through the second voltage follower circuit.

Preferably, the input data is a digital signal, the input signal voltage is an analog signal, and the driving device further comprises a digital-to-analog signal conversion circuit which converts a digital signal voltage corresponding to the input data into the input signal voltage having a corresponding analog signal voltage.

Preferably, the pixel is a display pixel which is provided on a display panel to display an image, and the input data is display data to cause the display pixel to display a desired image.

The first voltage follower circuit and the second voltage follower circuit can include a plurality of thin-film transistors. Each thin-film transistor comprises, e.g., a polysilicon thin-film transistor.

Preferably, the first voltage follower circuit includes a plurality of first thin-film transistors, the second voltage follower circuit includes a plurality of second thin-film transistors, the first voltage follower circuit and the second voltage follower circuit have the same circuit arrangement, and the plurality of second thin-film transistors corresponding to the first thin-film transistors have the same transistor size. Alternatively, one of the plurality of second thin-film transistors corresponding to the first thin-film transistors has the same ratio of a channel length to a channel width, and the channel width of the second thin-film transistor can be set smaller than the channel width of the first thin-film transistor.

The first voltage follower circuit has a first noninverting input terminal, a first inverting input terminal, and a first output terminal, the second voltage follower circuit has a second noninverting input terminal, a second inverting input terminal, and a second output terminal, the first output terminal is connected to the second noninverting input terminal, and the second output terminal can be connected to the second inverting input terminal and the first inverting input terminal. The first voltage follower circuit has a first operational amplifier which has the first noninverting input terminal, the first inverting input terminal, and the first output terminal, the second voltage follower circuit has a second operational amplifier which has the second noninverting input terminal, the second inverting input terminal, and the second output terminal, and the first operational amplifier and the second operational amplifier preferably have the same input/output characteristic.

### BRIEF DESCRIPTION OF THE SEVERAL VIEWS OF THE DRAWING

FIG. 1 is a schematic block diagram showing an arrangement example of a liquid crystal display device to which a driving device according to the present invention is applied;

FIG. 2 is a block diagram showing the arrangement of the main part of the liquid crystal display device according to the embodiment;

FIG. 3 is a schematic block diagram showing an arrangement example of a signal driver applied to the display device according to the embodiment;

FIG. 4 is a circuit diagram showing an arrangement of a buffer circuit according to the embodiment;

FIGS. 5A and 5B are graphs showing results obtained by verifying the input/output characteristic and output voltage accuracy when the buffer circuit according to the embodiment is constituted by using polysilicon transistors;

FIGS. 6A and 6B are graphs showing results obtained by verifying the output voltage accuracy when the buffer circuit according to the embodiment is constituted by using polysilicon transistors;

FIG. 7 is a circuit diagram showing another arrangement of the buffer circuit according to the embodiment;

FIG. 8 is a circuit diagram showing the arrangement of a buffer circuit according to a prior art;

FIG. 9 is a circuit diagram showing an example of the circuit arrangement of an operational amplifier used in the buffer circuit according to the prior art; and

FIGS. 10A and 10B are graphs showing results obtained by verifying the input/output characteristic when the buffer circuit according to the prior art is constituted by using polysilicon transistors.

### DETAILED DESCRIPTION OF THE INVENTION

An output circuit, and a driving circuit having such an output circuit according to the present invention will be described below in detail on the basis of the embodiment illustrated in the drawing.

In the case to be described below, the output circuit of the embodiment is applied to the digital driving signal driver circuit of a liquid crystal display device. However, the embodiment to which the present invention can be applied is not limited to this. For example, the present invention may be applied to, e.g., an analog driving signal driver circuit having no D/A converter. The present invention can also be applied not only to the driving circuit of a liquid crystal display device but also to the driving circuit of a self-luminescence type display device which has, as display pixels, light-emitting elements such as organic EL elements.

A display device to which the driving device having the output circuit according to the present invention can be applied will be described briefly with reference to the accompanying drawings.

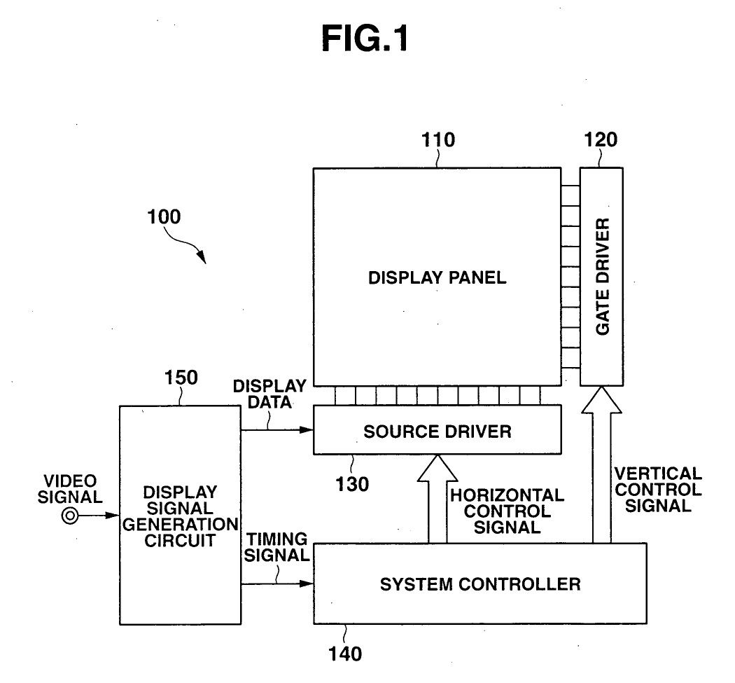

FIG. 1 is a schematic block diagram showing an arrangement example of a liquid crystal display device to which the driving device according to the present invention is applied.

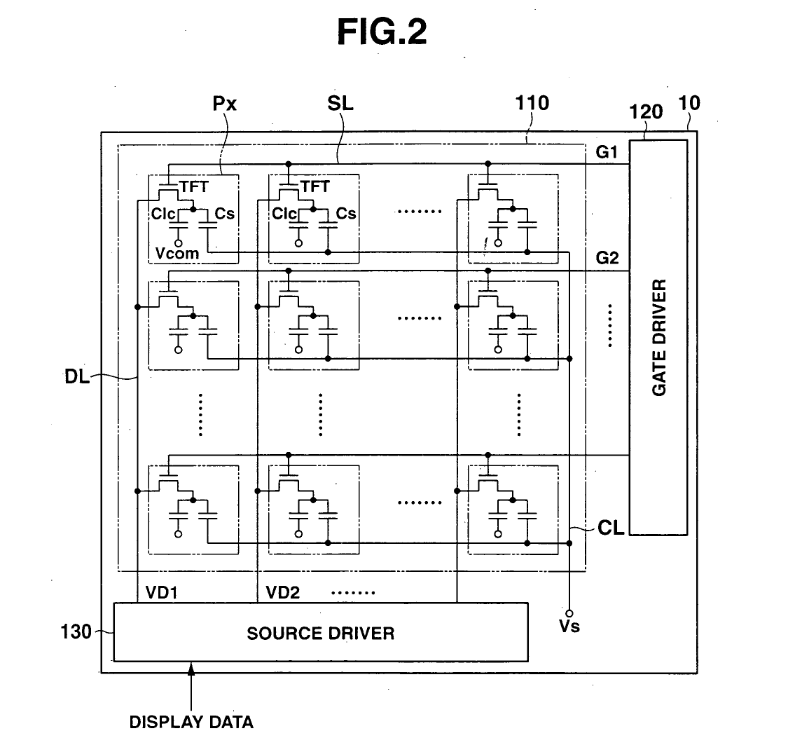

FIG. 2 is a block diagram showing the arrangement of the main part of the liquid crystal display device according to the embodiment.

As shown in FIGS. 1 and 2, a liquid crystal display device 100 according to this embodiment comprises a display panel 110, scan driver or gate driver 120, signal driver or source driver (display driving device) 130, LCD or system controller 140, display signal generation circuit 150, and common voltage driving amplifier (not shown). The display panel 110 has a plurality of scan lines (gate lines) SL, a plurality of signal lines (source lines) DL, and a plurality of display pixels Px on one transparent substrate 10 of a pair of transparent substrates such as glass substrates. The scan lines SL and signal lines DL are arranged in the row and column directions perpendicularly to each other. The display pixels Px are two-dimensionally arrayed near the intersections between the scan lines SL and the signal lines DL. The scan driver 120 is formed on, e.g., said one transparent substrate 10 and sequentially applies a scan signal to each scan line at a predetermined timing. The signal driver 130 applies a display signal voltage based on display data to each signal line. The LCD controller 140 generates and outputs at least control signals (vertical and horizontal control signals) to control the operation states of the scan driver 120 and signal driver 130. The display signal generation circuit 150 supplies, to the signal driver 130, display data containing, e.g., a digital signal based on a video signal input from the outside of the liquid crystal display device 100. The display signal generation circuit 150 also supplies a timing signal such as a horizontal sync signal or vertical sync signal based on the video signal to the LCD controller 140. The common voltage driving amplifier applies a common signal voltage with a predetermined voltage polarity to a common electrode arranged commonly for all display pixels.

Each display pixel Px in the display panel 110 includes, e.g., a pixel transistor TFT, pixel capacitance (liquid crystal capacitance) Clc, and auxiliary capacitance (storage capacitance) Cs, as shown in FIG. 2. The current path (source electrode−drain electrode) of the pixel transistor TFT is connected between the pixel electrode and the signal line DL. The control terminal (gate electrode) of the pixel transistor TFT is connected to the scan line SL. The pixel capacitance Clc includes liquid crystal molecules which are held between each pixel electrode of the display pixels Px and a common electrode commonly arranged to oppose the pixel electrodes of the display pixels Px. The auxiliary capacitance Cs is connected in parallel to the pixel capacitance Clc to hold the signal voltage applied to the pixel capacitance Clc.

The gate driver 120 sequentially applies a scan signal to each scan line of the display panel 110 on the basis of a vertical control signal output from the LCD controller 140 to set the display pixels of the row in the selected state.

The source driver 130 receives and holds display data for each row on the basis of a horizontal control signal output from the LCD controller 140. In addition, the signal driver 130 supplies at once a display signal voltage corresponding to the held display data to the display pixels of the row set in the selected state by the scan driver 120 through the signal lines. With this operation, the display data is written in the display pixels. The detailed arrangement of the signal driver will be described later.

The display signal generation circuit 150 extracts timings signals such as a horizontal sync signal and vertical sync signal from a video signal (composite video signal) supplied from, e.g., the outside of the liquid crystal display device 100 and supplies the timing signals to the LCD controller 140. The display signal generation circuit 150 also generates display data containing a digital signal corresponding to the video signal and outputs the display data to the signal driver 130. When the video signal is a digital video signal, the display signal generation circuit 150 extracts the digital video signal and outputs it to the signal driver 130 as display data.

On the basis of various kinds of timing signals supplied from the display signal generation circuit 150, the LCD controller 140 generates a horizontal control signal and vertical control signal and supplies them to the scan driver 120 and signal driver 130. In addition, the LCD controller 140 generates a driving control signal synchronous with the vertical control signal and applies a common signal voltage having a predetermined voltage value to the common electrode of the display panel 110. In the display device 100 having the above-described arrangement, on the basis of the vertical control signal, the scan driver 120 sequentially applies a scan signal to each scan line for each horizontal scan period to set the display pixels of each row in the selected state. In this state, on the basis of the horizontal control signal, the signal driver 130 outputs a display signal voltage corresponding to display data supplied from the display signal generation circuit 150. The display signal voltage is supplied to the display pixels of the row set in the selected state at once. When this operation is repeatedly executed for the rows of the display panel 110, desired image information based on the video signal is displayed on the liquid crystal display panel 110.

A detailed example of the signal driver (driving device) applied to the above-described display device will be described next in detail with reference to the accompanying drawing.

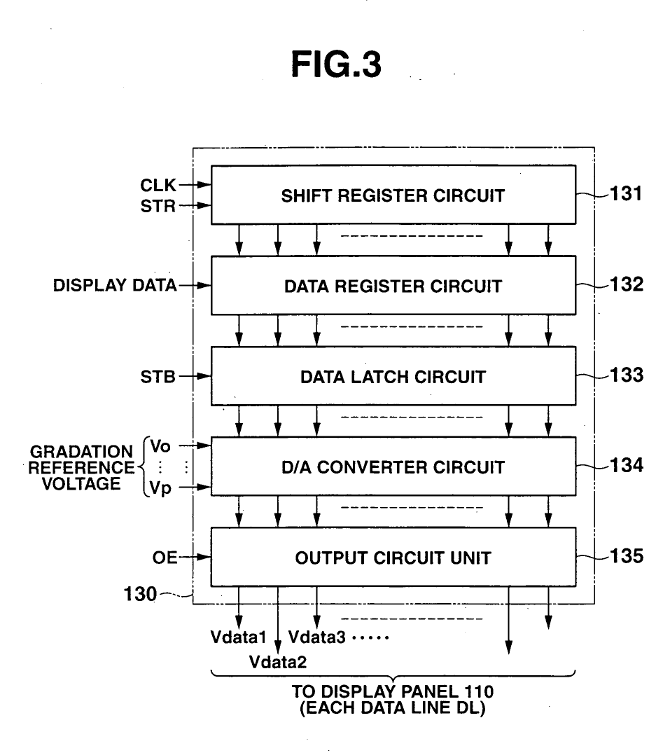

FIG. 3 is a schematic block diagram showing an arrangement example of the signal driver applied to the display device according to this embodiment.

As shown in FIG. 3, the signal driver 130 applied to the display device according to this embodiment includes, e.g., a shift register circuit 131, data register circuit 132, data latch circuit 133, D/A converter (digital-to-analog signal conversion means) 134, and output circuit unit 135. The shift register circuit 131 sequentially outputs a shift signal on the basis of a shift clock signal CLK and sampling start signal STR in the horizontal control signal supplied from the system controller 140. The data register circuit 132 sequentially receives display data of one row containing a digital signal supplied from the display signal generation circuit 150 on the basis of the input timing of the shift signal. On the basis of a data latch signal STB, the data latch circuit 133 collectively holds the display data of one row received by the data register circuit 132. The D/A converter 134 converts the held display data into a predetermined analog signal voltage on the basis of gradation reference voltages V0 to Vp. The output circuit unit 135 outputs the analog signal voltage as a display signal voltage Vdata (Vdata1, Vdata2, Vdata3, . . . ) at a timing based on an output enable signal OE serving as a data control signal and applies the display signal voltage Vdata to each signal line DL arranged on the display panel 110.

The signal driver 130 generates the display signal voltage (analog signal) Vdata1 corresponding to the display data containing the digital signal supplied from the display signal generation circuit 150 and outputs the display signal voltage to the signal lines DL at once at a predetermined timing.

As will be described below, in the output circuit unit 135, a buffer circuit formed from polysilicon thin-film transistors according to the present invention is arranged for each signal line.

With this arrangement, in the present invention, at least the output circuit unit 135 of the signal driver 130 can be formed integrally on one of the transparent substrates 10 by which the display panel 110 is formed.

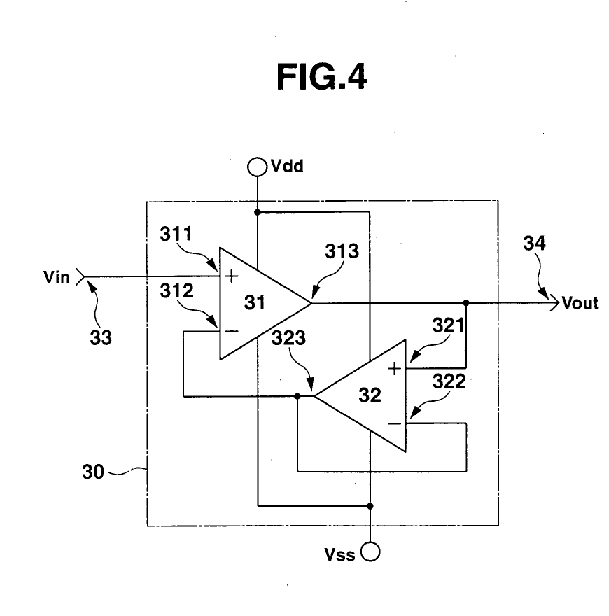

FIG. 4 is a circuit diagram showing the arrangement of the buffer circuit according to this embodiment.

As shown in FIG. 4, a buffer circuit 30 according to this embodiment includes a first operational amplifier 31 and second operational amplifier 32 which respectively operate upon receiving a high-level power supply voltage Vdd (e.g., 12V) and low-level power supply voltage Vss (e.g., 0V).

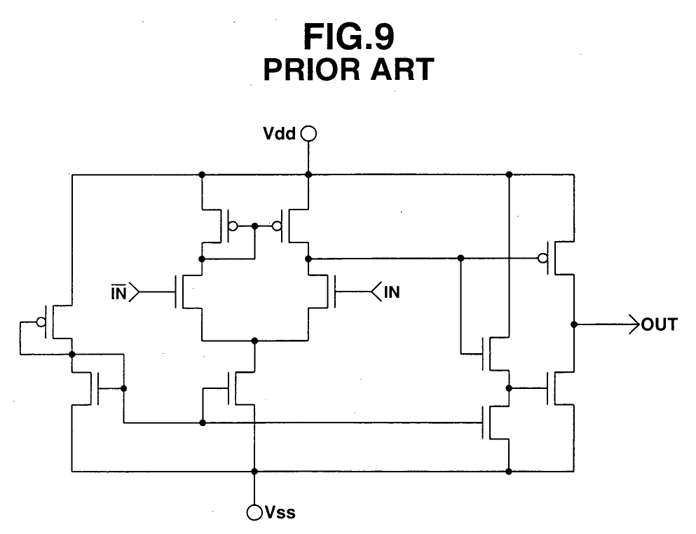

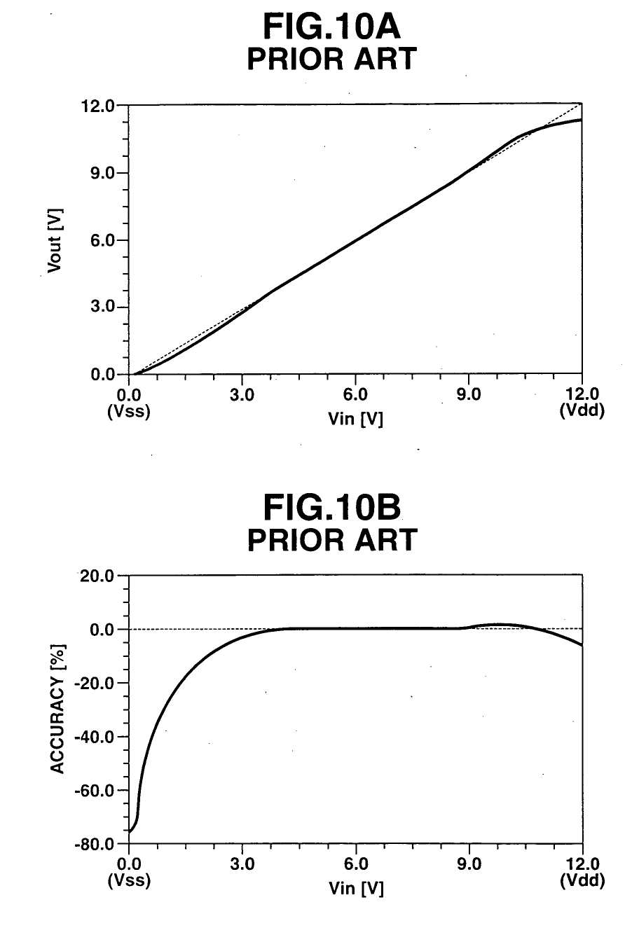

Each of the first and second operational amplifiers 31, 32 in the buffer circuit 30 has the same circuit arrangement as in, e.g., FIG. 9, including a plurality of transistors. Each transistor is a thin-film transistor (e.g., polysilicon thin-film transistor). In the plurality of thin-film transistors (first thin-film transistors) included in the first operational amplifier 31 and the plurality of thin-film transistors (second thin-film transistors) included in the second operational amplifier 32, corresponding thin-film transistors have the same voltage vs. current characteristic. That is, the first and second operational amplifiers 31, 32 have the same input/output characteristic. In the plurality of thin-film transistors (first thin-film transistors) included in the first operational amplifier 31 and the plurality of thin-film transistors (second thin-film transistors) included in the second operational amplifier 32, for example, corresponding thin-film transistors have the same transistor size (channel length and channel width).

The second operational amplifier 32 constitutes the same voltage follower circuit (second voltage follower circuit) as the above-described conventional voltage follower circuit shown in FIG. 8 by connecting an output terminal (second output terminal) 323 to an inverting input terminal (second inverting input terminal) 322.

An inverting input terminal (first inverting input terminal) 312 and output terminal (first output terminal) 313 of the first operational amplifier 31 are connected to the output terminal (second output terminal) 323 and noninverting input terminal (second noninverting input terminal) 321 of the second operational amplifier 32, respectively. That is, the output terminal (first output terminal) 313 and inverting input terminal (first inverting input terminal) 312 of the first operational amplifier 31 are connected through the second operational amplifier 32.

Hence, the first operational amplifier 31 is designed to negatively feed back the output signal voltage through the voltage follower circuit by the second operational amplifier 32. The first operational amplifier 31 actually constitutes a voltage follower circuit (first voltage follower circuit) through the voltage follower circuit by the second operational amplifier 32.

The buffer circuit 30 is constituted by combining two voltage follower circuits, i.e., the first and second voltage follower circuits. That is, the entire buffer circuit 30 is designed to actually function as one voltage follower circuit.

As the operation of the buffer circuit 30, when an input signal voltage Vin is input from an input voltage terminal 33, the input signal voltage Vin is input to the first operational amplifier 31 from a noninverting input terminal (first noninverting input terminal) 311.

An output signal voltage Vout output from the output terminal 313 of the first operational amplifier 31 is fed back to the inverting input terminal 312 of the first operational amplifier 31 through the second operational amplifier 32. Since the second operational amplifier 32 serves as the voltage follower circuit, the shift of the voltage fed back to the inverting input terminal 312 of the first operational amplifier 31 with respect to the output signal voltage Vout output from the output terminal 313 is suppressed, and the feedback operation is satisfactorily executed. The feedback operation of the output signal voltage Vout is improved and satisfactorily executed especially when the input signal voltage Vin is close to the high-level power supply voltage and low-level power supply voltage (Vdd and Vss). Hence, the shift between the input and output signal voltages is suppressed.

In other words, since the error of the output signal voltage of the first operational amplifier 31 is emphasized by the second operational amplifier 32 and negatively fed back to the first operational amplifier 31, the shift between the input and output signal voltages in the buffer circuit 30 is suppressed.

Hence, the buffer circuit 30 of this embodiment, which is formed from thin-film transistors (e.g., polysilicon thin-film transistor), can output an accurate voltage with a suppressed shift with respect to the input signal voltage Vin from an output voltage terminal 34 as the output signal voltage Vout, unlike the conventional voltage follower circuit constituted by directly connecting the output terminal 313 and inverting input terminal 312, as shown in FIG. 8.

A result obtained by verifying the output characteristic of the buffer circuit 30 will be described next.

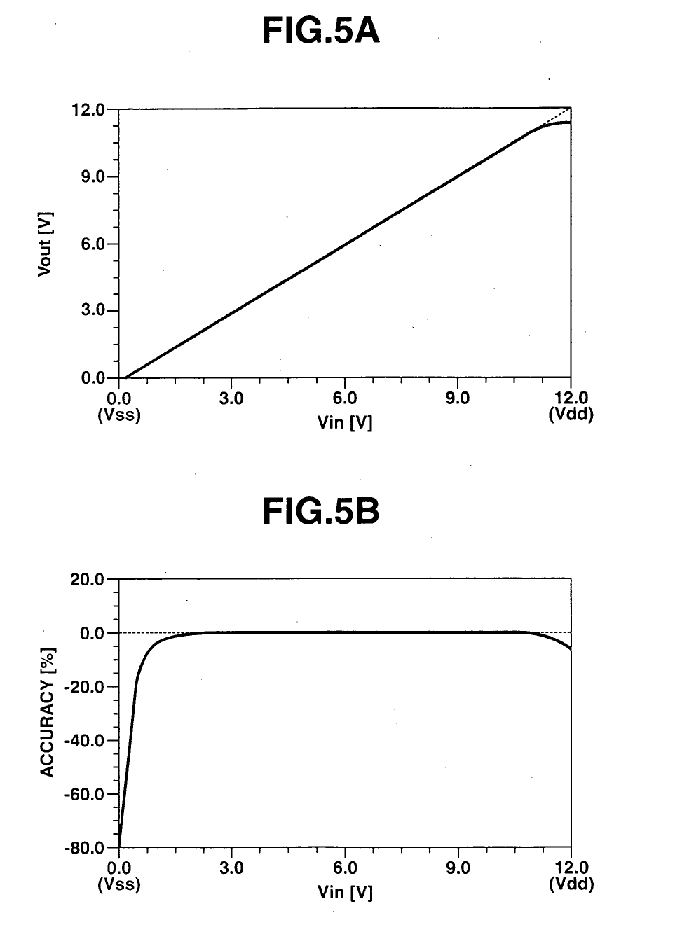

FIGS. 5A and 5B are graphs showing results obtained by verifying the input/output characteristic and output voltage accuracy when the buffer circuit according to this embodiment is constituted by using polysilicon thin-film transistors.

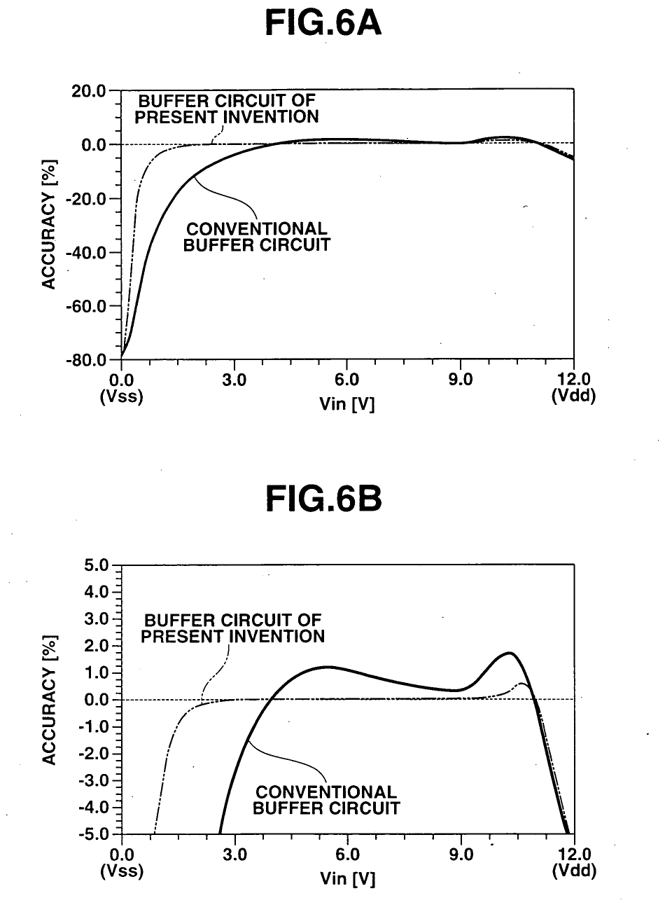

FIGS. 6A and 6B are graphs showing comparison of output signal voltage accuracy when the buffer circuit according to this embodiment and the buffer circuit of the prior art are constituted by using polysilicon thin-film transistors.

As shown in FIGS. 5A and 5B, when the buffer circuit 30 of this embodiment is constituted by using polysilicon thin-film transistors, the shift of the output signal voltage Vout with respect to the input signal voltage Vin is reduced, and the accuracy of the output signal voltage Vout increases in almost the entire region of the input signal voltage Vin from the low-level power supply voltage Vss (e.g., 0V) to the high-level power supply voltage Vdd (e.g., 12V).

FIG. 6A shows comparison of output signal voltage accuracy between the buffer circuit 30 of this embodiment and the buffer circuit 9 of the prior art, which include polysilicon thin-film transistors. According to FIG. 6A, in the output characteristic (two-dots chain line) of the buffer circuit 30, the shift between the input and output signal voltages is obviously improved especially when the input signal voltage Vin is close to the high-level power supply voltage and low-level power supply voltage (Vdd and Vss), as compared to the output characteristic (solid line) of the conventional buffer circuit. Especially, the accuracy near the low-level power supply voltage Vss (e.g., 0V) increases.

According to FIG. 6B in which the ±5% range is enlarged, the accuracy almost near the center of the input signal voltage is also higher in the buffer circuit 30 of this embodiment as shown by two-dots chain line, although this accuracy is relatively high even in the conventional buffer circuit 9.

In the buffer circuit 30 of this embodiment, the first operational amplifier 31 and second operational amplifier 32 are provided. The noninverting input terminal 311 is connected to the input voltage terminal 33. The output terminal 313 is connected to the output voltage terminal 34. The noninverting input terminal 321 is connected to the output terminal 313. The inverting input terminal 322 is connected to the output terminal 323 and inverting input terminal 312. With this arrangement, the difference between the input and output signal voltages in the first operational amplifier 31 is enlarged by the second operational amplifier 32 and negatively fed back to the first operational amplifier 31. For this reason, a more accurate voltage is output as the output signal voltage Vout, as compared to the conventional buffer circuit 9 by the voltage follower circuit.

When the buffer circuit 30 is applied to the output circuit unit 135 (FIG. 3) of the signal driver 130, the analog signal voltage corresponding to display data, which is output from the D/A converter 134, can accurately be applied to each signal line DL of the display panel 110. In addition, a signal voltage accurately corresponding to the gradation of the display data can be supplied to the display panel 110 so that accurate gradation display can be executed.

In the above-described embodiment, the first operational amplifier 31 and second operational amplifier 32 have the same input/output characteristic. The corresponding transistors of the plurality of thin-film transistors which constitute the operational amplifiers 31, 32 have the same transistor size. However, the present invention is not limited to this.

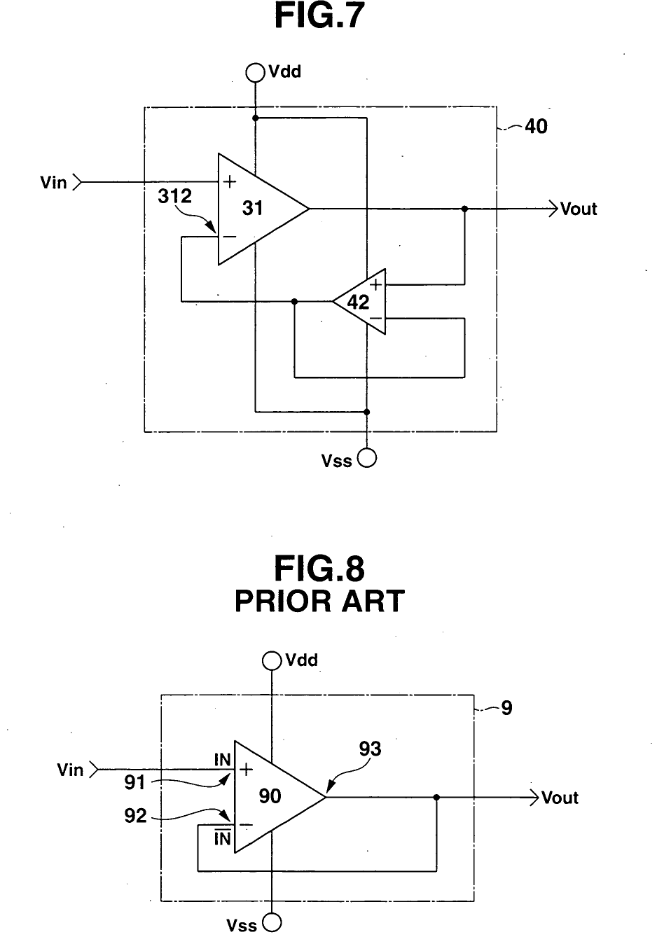

FIG. 7 is a circuit diagram showing another arrangement of the buffer circuit according to this embodiment.

The first operational amplifier 31 which drives a signal line as a load must have a relatively large current driving capability to do it. However, the second operational amplifier 32 which only drives the inverting input terminal 312 of the first operational amplifier 31 can have a relatively small current driving capability necessary and sufficient for doing it.

Hence, the size of the plurality of thin-film transistors (second thin-film transistors) which constitute the second operational amplifier 32 may be set as follows. The corresponding ones of the thin-film transistors have the same ratio of a channel length L to a channel width W. The thin-film transistors have the same voltage vs. current characteristic. The channel width W is decreased (scaled down) so that a current driving capability minimum and sufficient for driving the inverting input terminal 312 is obtained.

More specifically, as shown in FIG. 7, a small operational amplifier 42 may be applied in place of the second operational amplifier 32. The operational amplifier 42 is scaled down to reduce the current driving capability while maintaining the same input/output characteristic as that of the first operational amplifier 31. Even in this case, the difference between the input and output signal voltages in the first operational amplifier 31 is increased by the second operational amplifier 42 and negatively fed back to the first operational amplifier 31. For this reason, a buffer circuit 40 which outputs a more accurate voltage as the output signal voltage Vout, as compared to the conventional buffer circuit 9 by the voltage follower circuit, can be implemented. The result obtained by simulating and verifying the output characteristic of the buffer circuit 40 is the same as in FIGS. 5A and 5B described above because the operational amplifier 42 has the same input/output characteristic as that of the first operational amplifier 31.

In this case, since the size of the operational amplifier 42 can be reduced, the circuit area can be reduced. Hence, when the driving circuit is formed integrally with the display panel, any increase in area of the driving circuit portion can be suppressed, and the outer peripheral portion of the display surface can be narrowed.

1. An output circuit which outputs an output signal voltage corresponding to an input signal voltage comprising:
at least a first voltage follower circuit and a second voltage follower circuit,
wherein the input signal voltage is applied to the first voltage follower circuit, and the output signal voltage is output therefrom, and
the output signal voltage is negatively fed back to the first voltage follower circuit through the second voltage follower circuit.

2. A circuit according to claim 1, wherein the first voltage follower circuit and the second voltage follower circuit include a plurality of thin-film transistors.

3. A circuit according to claim 2, wherein each of the thin-film transistors includes a polysilicon thin-film transistor.

4. A circuit according to claim 2, wherein
the first voltage follower circuit includes a plurality of first thin-film transistors,
the second voltage follower circuit includes a plurality of second thin-film transistors,
the first voltage follower circuit and the second voltage follower circuit have the same circuit arrangement, and
one of the plurality of second thin-film transistors and corresponding one of the first thin-film transistors have the same transistor size.

5. A circuit according to claim 2, wherein
the first voltage follower circuit includes a plurality of first thin-film transistors,
the second voltage follower circuit includes a plurality of second thin-film transistors,
the first voltage follower circuit and the second voltage follower circuit have the same circuit arrangement, and
one of the plurality of second thin-film transistors and corresponding one of the first thin-film transistors have the same ratio of a channel length to a channel width, and the channel width of the second thin-film transistor is set smaller than the channel width of the first thin-film transistor.

6. A circuit according to claim 1, wherein
the first voltage follower circuit has a first noninverting input terminal, a first inverting input terminal, and a first output terminal,
the second voltage follower circuit has a second noninverting input terminal, a second inverting input terminal, and a second output terminal,
the first output terminal is connected to the second noninverting input terminal, and
the second output terminal is connected to the second inverting input terminal and the first inverting input terminal.

7. A circuit according to claim 6, wherein
the first voltage follower circuit has a first operational amplifier which has the first noninverting input terminal, the first inverting input terminal, and the first output terminal,
the second voltage follower circuit has a second operational amplifier which has the second noninverting input terminal, the second inverting input terminal, and the second output terminal, and
the first operational amplifier and the second operational amplifier have the same input/output characteristic.

8. A driving device which drives pixel comprising:
an output circuit unit to which an input signal voltage corresponding to input data is applied and which outputs an output signal voltage corresponding to the input signal voltage to the pixels,
the output circuit unit including at least a first voltage follower circuit and a second voltage follower circuit,
wherein the input signal voltage is applied to the first voltage follower circuit, and the output signal voltage is output therefrom, and
the output signal voltage is negatively fed back to the first voltage follower circuit through the second voltage follower circuit.

9. A device according to claim 8, wherein
the input data is a digital signal,
the input signal voltage is an analog signal, and
which further comprises a digital-to-analog signal conversion circuit which converts a digital signal voltage corresponding to the input data into the input signal voltage having a corresponding analog signal voltage.

10. A device according to claim 8, wherein
the pixels are display pixels which are provided on a display panel to display an image, and
the input data includes display data to cause the display pixels to display the image.

11. A device according to claim 8, wherein the first voltage follower circuit and the second voltage follower circuit include a plurality of thin-film transistors.

12. A device according to claim 11, wherein each of the thin-film transistor includes a polysilicon thin-film transistor.

13. A device according to claim 11, wherein
the first voltage follower circuit includes a plurality of first thin-film transistors,
the second voltage follower circuit includes a plurality of second thin-film transistors,
the first voltage follower circuit and the second voltage follower circuit have the same circuit arrangement, and
one of the plurality of second thin-film transistors and corresponding one of the first thin-film transistors have the same transistor size.

14. A device according to claim 11, wherein
the first voltage follower circuit includes a plurality of first thin-film transistors,
the second voltage follower circuit includes a plurality of second thin-film transistors,
the first voltage follower circuit and the second voltage follower circuit have the same circuit arrangement, and
one of the plurality of second thin-film transistors and corresponding one of the first thin-film transistors have the same ratio of a channel length to a channel width, and the channel width of the second thin-film transistor is set smaller than the channel width of the first thin-film transistor.

15. A device according to claim 8, wherein
the first voltage follower circuit has a first noninverting input terminal, a first inverting input terminal, and a first output terminal,
the second voltage follower circuit has a second noninverting input terminal, a second inverting input terminal, and a second output terminal,
the first output terminal is connected to the second noninverting input terminal, and
the second output terminal is connected to the second inverting input terminal and the first inverting input terminal.

16. A device according to claim 15, wherein
the first voltage follower circuit has a first operational amplifier which has the first noninverting input terminal, the first inverting input terminal, and the first output terminal,
the second voltage follower circuit has a second operational amplifier which has the second noninverting input terminal, the second inverting input terminal, and the second output terminal, and
the first operational amplifier and the second operational amplifier have the same input/output characteristic.
